(19) United States
(12) Patent Application Publication
(10) Pub. No.: US 2007/0069304 A1
(43) Pub. Date: Mar. 29, 2007

(54) Semiconductor device and method for fabricating the same

(76) Inventors: Kazuhiko Aida, Chiba (JP); Junji Hirase, Osaka (JP); Akio Sebe, Osaka (JP); Naoki Kotani, Hyogo (JP); Shinji Takeoka, Osaka (JP); Gen Okazaki, Hyogo (JP)

Correspondence Address: MCDERMOTT WILL & EMERY LLP, 600 13TH STREET, NW, WASHINGTON, DC, 20005-3096, US

(21) Appl. No.: 11/450,349

(22) Filed: Jun. 12, 2006

(30) Foreign Application Priority Data
Sep. 26, 2005 (JP) 2005-278200

(51) Int. Cl. H01L 29/94

(52) U.S. Cl. 257/369

(57) ABSTRACT

A semiconductor device includes: a first element region and a second element region formed on a substrate to be adjacent to each other with an isolation region interposed therebetween; a first gate insulating film formed on the first element region; a second gate insulating film formed on the second element region; and a gate electrode continuously formed on the first gate insulating film, the isolation region and the second gate insulating film. The gate electrode includes a first silicided region formed to come into contact with the first gate insulating film, a second silicided region which is formed to come into contact with the second gate insulating film and is of a different composition from the first silicided region, and a conductive anti-diffusion region composed of a non-silicided region formed in a part of the gate electrode located on the isolation region and between the first element region and the second element region.

### BACKGROUND OF THE INVENTION

(1) Field of the Invention

The present invention relates to semiconductor devices and methods for fabricating the same, and more particularly relates to techniques that can enhance the stability of gate electrodes and are effective at improving the reliability of semiconductor devices.

(2) Description of Related Art

In recent years, in order to increase the degree of integration and speed of semiconductor integrated circuits, alloys of metals offering low-resistance and stable properties or refractory metals have frequently been used also for fine gate electrode wirings. These materials are metallurgically stable toward heat and chemical solutions and of low resistance and high reliability, resulting in increases in the degree of integration and speed of semiconductor integrated circuits.

In a case where a gate electrode is continuously formed to cover element regions of a first conductivity type and a second conductivity type which are formed on a substrate to be adjacent to each other with an isolation region interposed therebetween, there is used a method in which respective parts of the gate electrode formed on the element regions of the first and second conductivity types are made of silicide materials of different compositions with the aim of improving the properties of each of elements (see J. A. Kittl et al., Symposium on VLSI Technology Digest of Technical Papers (2005), pp. 72-73).

FIGS. 17A through 17D and 18A through 18C are cross-sectional views taken along the gate width direction and illustrating process steps in a fabrication method for a known semiconductor device, more specifically, a semiconductor device having a dual-gate structure.

First, as illustrated in FIG. 17A, an isolation region 11 is formed in a semiconductor substrate 10 of silicon by shallow trench isolation (STI) to isolate a region in which an N-type MIS (metal insulator semiconductor) transistor is to be formed (hereinafter, referred to as “N-type MIS transistor formation region”) from a region in which a P-type MIS transistor is to be formed (hereinafter, referred to as “P-type MIS transistor formation region”). Thereafter, a first gate insulating film 12A and a second gate insulating film 12B both having a thickness of 2 nm and formed of a silicon oxide film are formed on parts of the semiconductor substrate 10 located in the N-type MIS transistor formation region and the P-type MIS transistor formation region, respectively. Then, a 150-nm-thick polycrystalline silicon film 13 is formed on the entire surface of the semiconductor substrate 10. Subsequently, the polycrystalline silicon film 13 and a set of the gate insulating films 12A and 12B are sequentially etched by photolithography and reactive ion etching (RIE), thereby patterning the polycrystalline silicon film 13 into the shape of a gate electrode. FIG. 19 illustrates a plan structure of a semiconductor substrate 10 on which a polycrystalline silicon film 13 is patterned into the shape of the gate electrode. Furthermore, although not illustrated, an N-type extension region, a P-type pocket region, a P-type extension region, and an N-type pocket region are formed. In addition, an approximately 10-nm-thick tetra ethyl ortho silicate (TEOS) film and an approximately 40-nm-thick silicon nitride film are sequentially deposited on the substrate by chemical vapor deposition (CVD) and then etched, thereby forming sidewalls.

Next, as illustrated in FIG. 17B, a resist film 14 is formed on the polycrystalline silicon film 13 to cover the P-type MIS transistor formation region and have an opening in the N-type MIS transistor formation region. Next, phosphorus (P⁺) ions are introduced, as N-type impurity ions, into the polycrystalline silicon film 13 by ion implantation using the resist film 14 as a mask at an implantation energy of 20 keV and a dose of 4×10¹⁵/cm². In this way, N-type source and drain regions (not shown) are formed. Furthermore, a part of the polycrystalline silicon film 13 located in the N-type MIS transistor formation region becomes an N-type polycrystalline silicon film 13A. Thereafter, the resist film 14 is removed.

Next, as illustrated in FIG. 17C, a resist film 15 is formed on the polycrystalline silicon film 13 to cover the N-type MIS transistor formation region and have an opening in the P-type MIS transistor formation region. Next, boron (B⁺) ions are introduced, as P-type impurity ions, into the polycrystalline silicon film 13 by ion implantation using the resist film 15 as a mask at an implantation energy of 0.5 keV and a dose of 3×10¹⁵/cm². In this way, P-type source and drain regions (not shown) are formed. Furthermore, a part of the polycrystalline silicon film 13 located in the P-type MIS transistor formation region becomes a P-type polycrystalline silicon film 13B. Thereafter, the resist film 15 is removed, and then the semiconductor substrate 10 is subjected to heat treatment, thereby activating the impurity ions introduced into the polycrystalline silicon film 13. In this case, the impurity ions diffuse in the polycrystalline silicon film 13. As a result, a PN boundary is formed at the boundary between the N-type MIS transistor formation region and the P-type MIS transistor formation region.

Next, as illustrated in FIG. 17D, a resist film 16 is formed on the polycrystalline silicon film 13 to cover the P-type MIS transistor formation region and have an opening-in the N-type MIS transistor formation region. Next, the N-type polycrystalline silicon film 13A is etched using the resist film 16 as a mask so that its approximately 80-nm-thick upper portion is removed. In other words, after this etching process, the N-type polycrystalline silicon film 13A that will become a part of a gate electrode located in the N-type MIS transistor formation region has a thickness of approximately 70 nm. Thereafter, the resist film 16 is removed.

Next, as illustrated in FIG. 18A, a resist film 17 is formed on the polycrystalline silicon film 13 to cover the N-type MIS transistor formation region and have an opening in the P-type MIS transistor formation region. Next, the P-type polycrystalline silicon film 13B is etched using the resist film 17 as a mask so that its approximately 110-nm-thick upper portion is removed. In other words, after this etching process, the P-type polycrystalline silicon film 13B that will become a part of a gate electrode located in the P-type MIS transistor formation region has a thickness of approximately 40 nm. Thereafter, the resist film 17 is removed.

Next, as illustrated in FIG. 18B, an approximately 120-nm-thick nickel (Ni) film 18 is deposited on the polycrystalline silicon film 13, and then the semiconductor substrate 10 is subjected to heat treatment at a temperature of approximately 350° C. for approximately 30 seconds, thereby causing a silicidation reaction between the polycrystalline silicon film 13 and the Ni film 18. Thereafter, an unreacted portion of the Ni film 18 is selectively removed, and then the semiconductor substrate 10 is additionally subjected to heat treatment at a temperature of approximately 520° C. for approximately 30 seconds. In this way, as illustrated in FIG. 18C, a NiSi film 19A is formed in the N-type MIS transistor formation region, and a Ni₃Si film 19B is formed in the P-type MIS transistor formation region. Since the polycrystalline silicon film 13 and the Ni film 18 are fully silicided, a fully silicided gate electrode formed of the NiSi film 19A is formed in the N-type MIS transistor formation region, and a fully silicided gate electrode formed of the Ni₃Si film 19B is formed in the P-type MIS transistor formation region.

### SUMMARY OF THE INVENTION

However, the known semiconductor device lacks its reliability due to the instability of its gate electrode.

In view of the above, an object of the present invention is to improve the reliability of a semiconductor device having a fully silicided dual-gate structure by enhancing the stability of a gate electrode thereof.

In order to achieve the above object, the present inventors studied a cause of the gate electrode of the known semiconductor device becoming instable, and finally obtained the following findings. In the known semiconductor device, the boundary between the NiSi film 19A and the Ni₃Si film 19B inevitably exists in the gate electrode. The heat treatment after the silicidation of the polycrystalline silicon film 13 and the Ni film 18 allows, at the above boundary, the reaction between the resultant suicides or interdiffusion of Ni. Therefore, it is likely that the shape of the boundary will be changed or the composition of each silicide will become instable. For example, as illustrated in FIG. 18C, Ni forming the Ni₃Si film 19B in the P-type MIS transistor formation region travels into the NiSi film 19A in the N-type MIS transistor formation region. As a result, the Ni₃Si film 19B is partly formed also in the N-type MIS transistor formation region. Therefore, the gate electrode characteristics in the N-type MIS transistor formation region become instable. More specifically, a portion of the gate electrode located at the boundary between silicides of different compositions are less stable than the other portion thereof and also deteriorates the stable operation and reliability of the semiconductor device.

In view of the above findings, the present inventors developed the invention in which a conductive anti-diffusion region for preventing the interdiffusion is formed at the boundary between silicides of different compositions in a gate electrode.

To be specific, a semiconductor device according to the present invention includes: a first element region and a second element region formed on a substrate to be adjacent to each other with an isolation region interposed therebetween; a first gate insulating film formed on the first element region; a second gate insulating film formed on the second element region; and a gate electrode continuously formed on the first gate insulating film, the isolation region and the second gate insulating film, wherein the gate electrode includes a first silicided region formed to come into contact with the first gate insulating film, a second silicided region which is formed to come into contact with the second gate insulating film and is of a different composition from the first silicided region, and a conductive anti-diffusion region composed of a non-silicided region formed in a part of the gate electrode located on the isolation region and between the first element region and the second element region.

In the semiconductor device of the present invention, the conductive anti-diffusion region may be a silicon region. In this case, the semiconductor device may further comprise: an impurity region of a first conductivity type formed in the first element region and an impurity region of a second conductivity type formed in the second element region, wherein the silicon region may be of the first or second conductivity type. In this case, no PN boundary exists in part of the silicon region serving as the conductive anti-diffusion region. More specifically, in the semiconductor device of the present invention, the part of the silicon region serving as the conductive anti-diffusion region is of P-type or N-type.

In the semiconductor device of the present invention, the silicon region may contain germanium.

In the semiconductor device of the present invention, the conductive anti-diffusion region may be formed in a lower portion of the gate electrode located on the isolation region; and at least one of the first silicided region and the second silicided region may extend over the conductive anti-diffusion region.

In the semiconductor device of the present invention, the first and second silicided regions may contain at least one of Co, Ti, Ni, and Pt.

In the semiconductor device of the present invention, an anti-silicidation film may be formed on the conductive anti-diffusion region.

A method for fabricating a semiconductor device according to the present invention comprises the steps of: (a) forming, on a substrate, a first element region and a second element region to be adjacent to each other with an isolation region interposed therebetween; (b) forming a first gate insulating film and a second gate insulating film on the first element region and the second element region, respectively; (c) continuously forming a silicon film that will become a gate electrode on the first gate insulating film, the isolation region and the second gate insulating film; (d) introducing an impurity of a first conductivity type into a part of the silicon film located on the first element region; (e) introducing an impurity of a second conductivity type into a part of the silicon film located on the second element region; (f) after the steps (d) and (e), forming an anti-silicidation film to at least partly cover a part of the silicon film located on the isolation region; and (g) after the step (f), forming a first silicided region by fully siliciding a part of the silicon film located on the first gate insulating film and forming a second silicided region by fully siliciding a part of the silicon film located on the second gate insulating film, wherein in the step (g), the first and second silicided regions are formed to be of different compositions and a conductive anti-diffusion region formed of part of the silicon film is left under the anti-silicidation film.

In the method of the present invention, the step (g) may include the step of forming a metal film on the silicon film and the anti-silicidation film, then causing the silicon film and the metal film to react with each other by heat treatment, and thereafter removing an unreacted portion of the metal film, thereby forming the first silicided region and the second silicided region. In this case, the metal film used in the step (g) may contain at least one of Co, Ti, Ni, and Pt. Furthermore, the impurity of the first conductivity type may be an N-type impurity, the impurity of the second conductivity type may be a P-type impurity, and in the step (g), a part of the metal film located on the second element region may have a larger thickness than a part thereof located on the first element region.

In the method of the present invention, a part of the silicon film that will become the conductive anti-diffusion region may be of the first or second conductivity type. In a case where a PN boundary exists in the silicon film that will become a gate electrode just after the completion of the steps (d) and (e), an anti-silicidation film is formed outside the PN boundary in the step (f). In other words, in the method of the present invention, a part of the silicon film that will become the conductive anti-diffusion region is of P-type or N-type.

In the method of the present invention, the anti-silicidation film may be formed of a silicon oxide film or a silicon nitride film.

In the method of the present invention, the silicon film may contain germanium.

In the method of the present invention, in the step (g), at least one of the first silicided region and the second silicided region may be formed to extend over the conductive anti-diffusion region.

The method of the present invention may further comprise the step of after the step (c), reducing the thicknesses of parts of the silicon film located on at least the first and second element regions.

In the method of the present invention, the impurity of the first conductivity type may be an N-type impurity, the impurity of the second conductivity type may be a P-type impurity, and the method further comprises the step of after the step (c), making a part of the silicon film located on the second element region thinner than a part thereof located on the first element region.

According to the present invention, a conductive anti-diffusion region for preventing inter-diffusion is formed at the boundary between silicides of different compositions in a fully-silicided dual-gate electrode. This can prevent such problems that due to interdiffusion between the suicides, the shapes of the silicides are changed or the compositions thereof become instable. In view of the above, the reliability of the semiconductor device can be improved by enhancing the stability of the gate electrode.

As described above, the present invention relates to a semiconductor device and a fabricating method for the same and is very useful when applied to a semiconductor device having a dual-gate structure, because the reliability of the semiconductor device can be improved by enhancing the stability of the gate electrode.

### BRIEF DESCRIPTION OF THE DRAWINGS

FIGS. 1A through 1D are cross-sectional views taken along the gate width direction and illustrating some of process steps in a fabricating method for a semiconductor device according to a first embodiment of the present invention.

FIGS. 2A through 2D are cross-sectional views taken along the gate width direction and illustrating some of the process steps in the fabricating method for a semiconductor device according to the first embodiment of the present invention.

FIG. 3 is a plan view illustrating one of the process steps in the fabricating method for a semiconductor device according to the first embodiment of the present invention.

FIG. 4 is a cross-sectional view taken along the gate width direction and illustrating an exemplary structure of a semiconductor device according to the first embodiment of the present invention.

FIGS. 5A through 5D are cross-sectional views taken along the gate width direction and illustrating some of process steps in a fabricating method for a semiconductor device according to a second embodiment of the present invention.

FIGS. 6A through 6D are cross-sectional views taken along the gate width direction and illustrating some of the process steps in the fabricating method for a semiconductor device according to the second embodiment of the present invention.

FIG. 7 is a plan view illustrating one of the process steps in the fabricating method for a semiconductor device according to the second embodiment of the present invention.

FIG. 8 is a cross-sectional view taken along the gate width direction and illustrating an exemplary structure of a semiconductor device according to the second embodiment of the present invention.

FIGS. 9A through 9D are cross-sectional views taken along the gate width direction and illustrating some of process steps in a fabricating method for a semiconductor device according to a third embodiment of the present invention.

FIGS. 10A through 10C are cross-sectional views taken along the gate width direction and illustrating some of the process steps in the fabricating method for a semiconductor device according to the third embodiment of the present invention.

FIG. 11 is a plan view illustrating one of the process steps in the fabricating method for a semiconductor device according to the third embodiment of the present invention.

FIG. 12 is a cross-sectional view taken along the gate width direction and illustrating an exemplary structure of a semiconductor device according to the third embodiment of the present invention.

FIGS. 13A through 13D are cross-sectional views taken along the gate width direction and illustrating some of process steps in a fabricating method for a semiconductor device according to a fourth embodiment of the present invention.

FIGS. 14A through 14D are cross-sectional views taken along the gate width direction and illustrating some of the process steps in the fabricating method for a semiconductor device according to the fourth embodiment of the present invention.

FIG. 15 is a plan view illustrating one of the process steps in the fabricating method for a semiconductor device according to the fourth embodiment of the present invention.

FIG. 16 is a cross-sectional view taken along the gate width direction and illustrating an exemplary structure of a semiconductor device according to the fourth embodiment of the present invention.

FIGS. 17A through 17D are cross-sectional views taken along the gate width direction and illustrating some of process steps in a known fabricating method for a semiconductor device.

FIGS. 18A through 18C are cross-sectional views taken along the gate width direction and illustrating some of the process steps in the known fabricating method for a semiconductor device.

FIG. 19 is a plan view illustrating one of the process steps in the known fabricating method for a semiconductor device.

### DETAILED DESCRIPTION OF THE INVENTION

### Embodiment 1

A semiconductor device according to a first embodiment of the present invention and a fabrication method for the same will be described hereinafter with reference to the drawings.

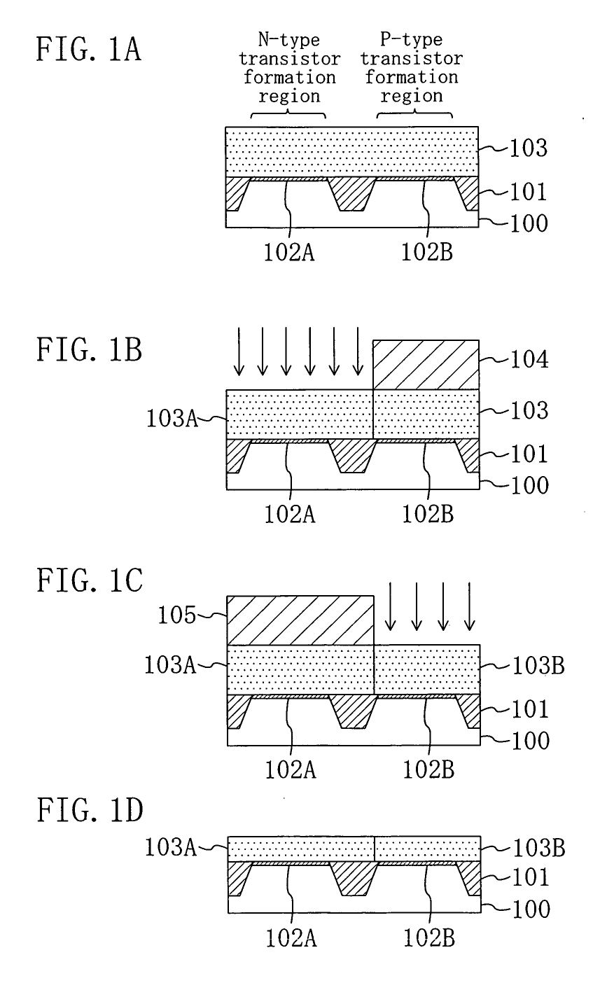

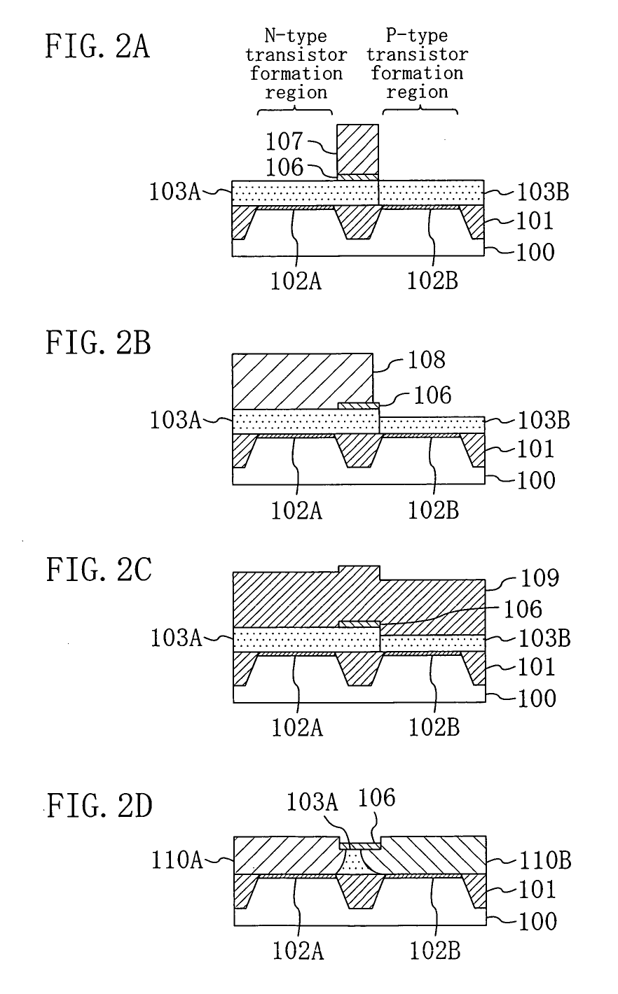

FIG. 1A through 1D and 2A through 2D are cross-sectional views taken along the gate width direction and illustrating process steps in the fabrication method for the semiconductor device according to the first embodiment, more specifically, a semiconductor device having a dual-gate structure.

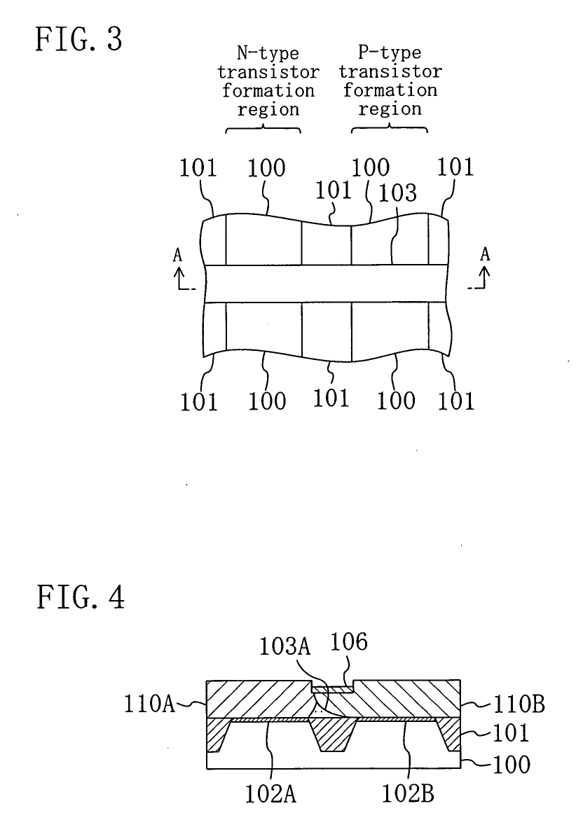

First, as illustrated in FIG. 1A, an isolation region 101 is formed in a semiconductor substrate 100 of, for example, silicon by STI to isolate an N-type MIS transistor formation region from a P-type MIS transistor formation region. Thereafter, a 2-nm-thick first gate insulating film 102A and a 2-nm-thick second gate insulating film 102B both formed of, for example, a silicon oxide film are formed on parts of the semiconductor substrate 100 located in the N-type MIS transistor formation region and the P-type MIS transistor formation region, respectively. Then, for example, a 150-nm-thick polycrystalline silicon film 103 is formed on the entire surface of the semiconductor substrate 100. In order to prevent various ions from being implanted into a channel region in implantation of the ions that will be described below, the polycrystalline silicon film 103 is set to have a larger thickness. Subsequently, the polycrystalline silicon film 103 and a set of the gate insulating films 102A and 102B are sequentially etched by photolithography and RIE, thereby patterning the polycrystalline silicon film 103 into the shape of a gate electrode. FIG. 3 illustrates a plan structure of a semiconductor substrate 100 on which a polycrystalline silicon film 103 is patterned into the shape of a gate electrode. Furthermore, although not illustrated, an N-type extension region and a P-type pocket region are formed in the N-type MIS transistor formation region, and a P-type extension region and an N-type pocket region are formed in the P-type MIS transistor formation region. In addition, for example, an approximately 10-nm-thick TEOS film and an approximately 40-nm-thick silicon nitride film are sequentially deposited on the substrate by CVD and then etched, thereby forming sidewalls formed of the TEOS film and the silicon nitride film on both sides of the patterned polycrystalline silicon film 103 having the shape of the gate electrode.

Next, as illustrated in FIG. 1B, a resist film 104 is formed on the polycrystalline silicon film 103 to cover the P-type MIS transistor formation region and have an opening in the N-type MIS transistor formation region. Next, for example, phosphorus (P⁺) ions are introduced, as N-type impurity ions, into the polycrystalline silicon film 103 by ion implantation using the resist film 104 as a mask at an implantation energy of 20 keV and a dose of 4×10¹⁵/cm². In this way, N-type source and drain regions (not shown) are formed. Furthermore, a part of the polycrystalline silicon film 103 located in the N-type MIS transistor formation region becomes an N-type polycrystalline silicon film 103A. Thereafter, the resist film 104 is removed.

In the process step illustrated in FIG. 1B, an area of the resist film 104 in which an opening is formed (hereinafter, referred to as “opening area of the resist film 104”) includes a non-silicided area (an area in which an anti-silicidation film 106 illustrated in FIG. 2A is to be formed). In other words, the opening area of the resist film 104 extends to a closer part of the isolation region 101 to the P-type MIS transistor formation region than the middle part thereof between the N-type MIS transistor formation region and the P-type MIS transistor formation region (preferably, to the end of the isolation region 101 located adjacent to the P-type MIS transistor formation region).

Next, as illustrated in FIG. 1C, a resist film 105 is formed on the polycrystalline silicon film 103 to cover the N-type MIS transistor formation region and have an opening in the P-type MIS transistor formation region. Next, for example, boron (B+) ions are introduced, as P-type impurity ions, into the polycrystalline silicon film 103 by ion implantation using the resist film 105 as a mask at an implantation energy of 0.5 keV and a dose of 3×10¹⁵/cm². In this way, P-type source and drain regions (not shown) are formed. Furthermore, a part of the polycrystalline silicon film 103 located in the P-type MIS transistor formation region becomes a P-type polycrystalline silicon film 103B. Thereafter, the resist film 105 is removed, and then the semiconductor substrate 100 is subjected to heat treatment, thereby activating the impurity ions introduced into the polycrystalline silicon film 103. In this case, the impurity ions diffuse in the polycrystalline silicon film 103. As a result, a PN boundary is formed at the boundary between the N-type MIS transistor formation region and the P-type MIS transistor formation region (exactly, on the end of the isolation region 101 located adjacent to the P-type MIS transistor formation region).

In the process step illustrated in FIG. 1C, an area of the resist film 105 in which an opening is formed (hereinafter, referred to as “opening area of the resist film 105”) does not include a non-silicided area (an area in which an anti-silicidation film 106 illustrated in FIG. 2A is to be formed). In other words, the opening area of the resist film 105 is not formed to extend to a closer part of the isolation region 101 to the P-type MIS transistor formation region than the middle part thereof between the N-type MIS transistor formation region and the P-type MIS transistor formation region. However, a part of the opening area of the resist film 105 preferably overlaps with an end portion of the isolation region 101 located adjacent to the P-type MIS transistor formation region.

Next, as illustrated in FIG. 1D, the entire surface of the polycrystalline silicon film 103 is etched, and, for example, an approximately 80-nm-thick upper portion thereof is removed. After this etching process, the N-type polycrystalline silicon film 103A that will become a part of a gate electrode located in the N-type MIS transistor formation region and the P-type polycrystalline silicon film 103B that will become a part of the gate electrode located in the P-type MIS transistor formation region each have a thickness of, for example, approximately 70 nm.

Next, as illustrated in FIG. 2A, an anti-silicidation film 106 is formed to cover at least one part of the polycrystalline silicon film 103 located on the isolation region 101 between the N-type MIS transistor formation region and the P-type MIS transistor formation region. To be specific, for example, an approximately 50-nm-thick silicon oxide film is formed on the entire surface of the polycrystalline silicon film 103, and then a resist film 107 is formed by lithography to cover an area in which an anti-silicidation film is to be formed. Thereafter, the silicon oxide film is etched using the resist film 107 as a mask, thereby forming an anti-silicidation film 106. Thereafter, the resist film 107 is removed.

In this embodiment, one end of the anti-silicidation film 106 is aligned with the PN boundary in the polycrystalline silicon film 103. In other words, the anti-silicidation film 106 is formed on an end part of the N-type polycrystalline silicon film 103A located on the isolation region 101, and thus the PN boundary does not exist under the middle part of the anti-silicidation film 106. The PN boundary may be located under an end part of the anti-silicificatin film 106 located adjacent to the P-type transistor formation region as long as it is located in a region of the polycrystalline silicon film 103 that will be formed into an Ni₃Si film 110B by silicidation in a process step illustrated in FIG. 2D. In other words, the end part of the anti-silicidation film 106 may overlap with the PN boundary.

Next, as illustrated in FIG. 2B, a resist film 108 is formed on the polycrystalline silicon film 103 to cover the N-type MIS transistor formation region and have an opening in the P-type MIS transistor formation region. Next, the P-type polycrystalline silicon film 103B is etched using the resist film 108 as a mask so that its approximately 30-nm-thick upper portion is removed. In other words, after this etching process, the P-type polycrystalline silicon film 103B that will become the part of the gate electrode located in the P-type MIS transistor formation region has a thickness of approximately 40 nm. Thereafter, the resist film 108 is removed.

In the process step illustrated in FIG. 2B, an area of the resist film 108 in which an opening is formed may overlap with part of the anti-silicidation film 106. In this case, the P-type polycrystalline silicon film 103B is etched using both the resist film 108 and the anti-silicidation film 106 as masks.

Next, as illustrated in FIG. 2C, for example, an approximately 120-nm-thick nickel (Ni) film 109 is deposited on the polycrystalline silicon film 103 and the anti-silicidation film 106, and then the semiconductor substrate 100 is subjected to heat treatment, for example, at a temperature of approximately 320° C. for approximately 30 seconds, thereby causing a silicidation reaction between the polycrystalline silicon film 103 and the Ni film 109. Thereafter, an unreacted portion of the Ni film 109 is selectively removed, and then the semiconductor substrate 100 is additionally subjected to heat treatment, for example, at a temperature of approximately 520° C. for approximately 30 seconds. In this way, as illustrated in FIG. 2D, a NiSi film 110A is formed which will become a part of a gate electrode located in the N-type MIS transistor formation region, and a Ni₃Si film 110B is formed which will become a part of the gate electrode located in the P-type MIS transistor formation region, Furthermore, an unreacted portion of the N-type polycrystalline silicon film 103A is left, as a conductive anti-diffusion region for preventing interdiffusion between the NiSi film 110A and the Ni₃Si film 110B, on the isolation region 101, i.e., under the anti-silicidation film 106.

Since in this embodiment the polycrystalline silicon film 103 and the Ni film 109 are fully silicided, a fully silicided gate electrode formed of the NiSi film 110A is formed in the N-type MIS transistor formation region to come into contact with the first gate insulating film 102A, and a fully silicided gate electrode formed of the Ni₃Si film 110B is formed in the P-type MIS transistor formation region to come into contact with the second gate insulating film 102B.

As described above, according to the first embodiment, a part of the N-type polycrystalline silicon film 103A serving as the conductive anti-diffusion region for preventing the interdiffusion is left between the NiSi film 110A and the Ni₃Si film 110B forming parts of a fully-silicided dual-gate electrode. This can prevent such problems that due to interdiffusion between suicides, the shapes of the NiSi film 110A and the Ni₃Si film 110B are changed or the compositions of the NiSi film 110A and the Ni₃Si film 110B become instable. In view of the above, the reliability of the semiconductor device can be improved by enhancing the stability of the gate electrode.

According to the first embodiment, the conductive anti-diffusion region corresponds to the N-type polycrystalline silicon film 103A in which no PN boundary exists. This can prevent the resistance of the gate electrode from increasing due to the conductive anti-diffusion region. In other words, the PN boundary in the polycrystalline silicon film 103 is formed on an end portion of the isolation region 101 located adjacent to the P-type MIS transistor formation region. Therefore, when the polycrystalline silicon film 103 is fully silicided, the PN boundary forms a part of the Ni₃Si film 110B. In view of the above, the N-type polycrystalline silicon film 103A in which no PN boundary exists is left as the conductive anti-diffusion region.

Although in the first embodiment the N-type polycrystalline silicon film 103A is used as the conductive anti-diffusion region, the P-type polycrystalline silicon film 103B may be used instead. Furthermore, although the polycrystalline silicon film 103 is used as the conductive anti-diffusion region, an amorphous film may be used instead.

Although in the first embodiment silicon is used as a material of the conductive anti-diffusion region, any other conductive material, such as silicon germanium, may be used instead.

In the first embodiment, the conductive anti-diffusion region formed of the N-type polycrystalline silicon film 103A is formed to extend from the top surface of the isolation region 101 to the back surface of the anti-silicidation film 106. However, otherwise, for example, as illustrated in FIG. 4, a conductive anti-diffusion region (for example, the N-type polycrystalline silicon film 103A) may be formed only in a lower portion of a gate electrode located on the isolation region 101, and both or one of a NiSi film 110A and a Ni₃Si film 110B may be formed to extend over the conductive anti-diffusion region.

Although in the first embodiment a Ni film is used to form a fully-silicided gate electrode, any other metal film, such as a cobalt (Co) film, a titanium (Ti) film, or a platinum (Pt) film, may be used instead. In other words, the fully-silicided gate electrode may contain at least one of Co, Ti, Ni, and Pt.

Although in the first embodiment a silicon oxide film is used as the anti-silicidation film 106, a silicon nitride (SiN) film, a Ti film, a titanium nitride (TiN) film, a tantalum (Ta) film, a tantalum nitride (TaN) film, a tungsten (W) film, or the like may be used instead.

In the first embodiment, the P-type polycrystalline silicon film 103B that will become a part of a gate electrode located in the P-type MIS transistor formation region has a smaller thickness than the N-type polycrystalline silicon film 103A that will become a part of the gate electrode located in the N-type MIS transistor formation region. However, instead of this or in addition to this, a part of the Ni film 109 located in the P-type MIS transistor formation region may have a larger thickness than a part thereof located in the N-type MIS transistor formation region.

### Embodiment 2

A semiconductor device according to a second embodiment of the present invention and a fabrication method for the same will be described hereinafter with reference to the drawings.

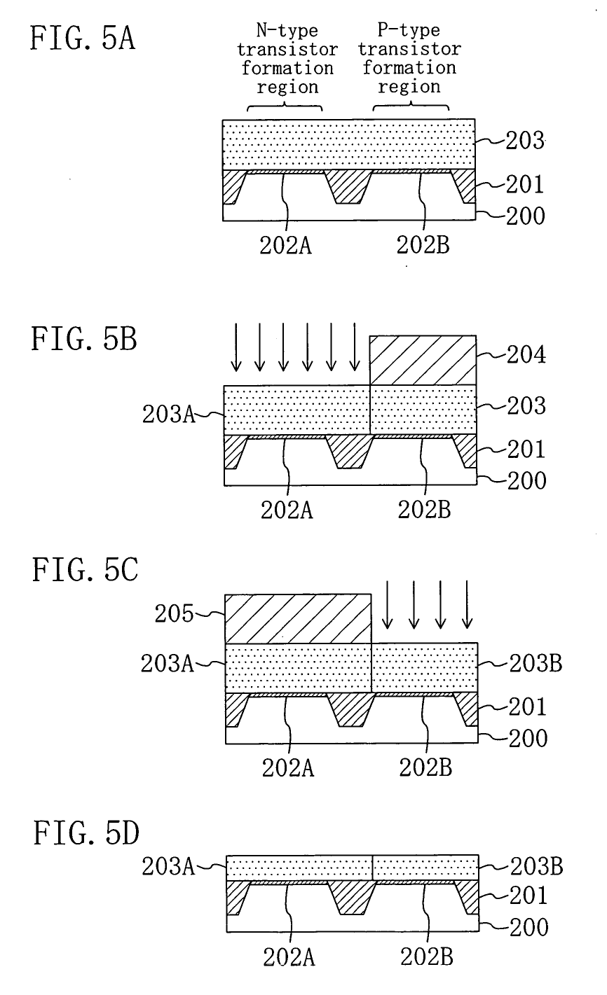

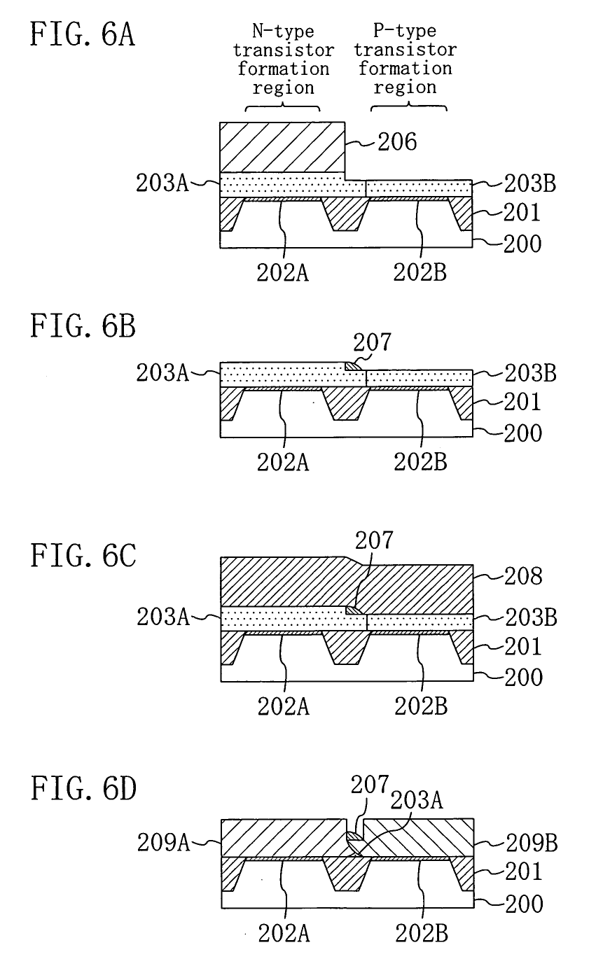

FIGS. 5A through 5D and 6A through 6D are cross-sectional views taken along the gate width direction and illustrating process steps in the fabrication method for the semiconductor device according to the first embodiment, more specifically, a semiconductor device having a dual-gate structure.

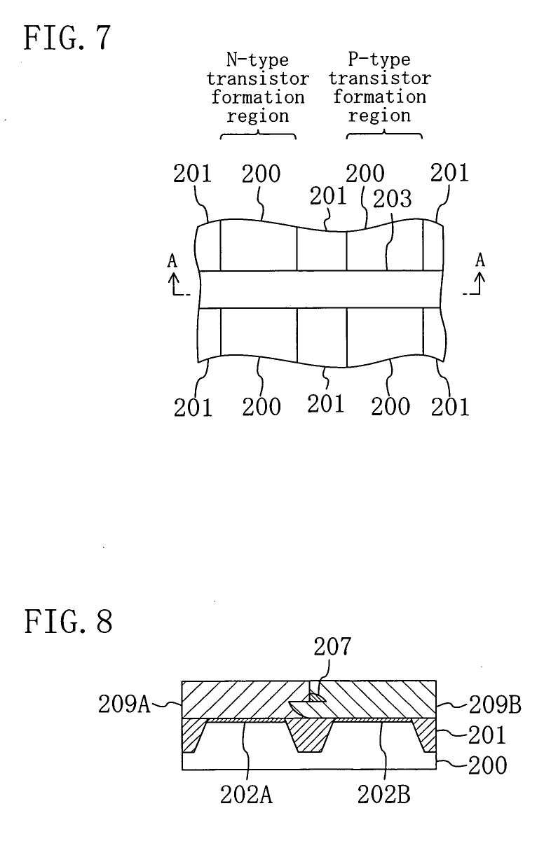

First, as illustrated in FIG. 5A, an isolation region 201 is formed in a semiconductor substrate 200 of, for example, silicon by STI to isolate an N-type MIS transistor formation region from a P-type MIS transistor formation region. Thereafter, a 2-nm-thick first gate insulating film 202A and a 2-nm-thick second gate insulating film 202B both formed of, for example, a silicon oxide film are formed on parts of the semiconductor substrate 200 located in the N-type MIS transistor formation region and the P-type MIS transistor formation region, respectively. Then, for example, a 150-nm-thick polycrystalline silicon film 203 is formed on the entire surface of the semiconductor substrate 200. In order to prevent various ions from being implanted into a channel region in implantation of the ions that will be described below, the polycrystalline silicon film 203 is set to have a larger thickness. Subsequently, the polycrystalline silicon film 203 and a set of the gate insulating films 202A and 202B are sequentially etched by photolithography and RIE, thereby patterning the polycrystalline silicon film 203 into the shape of a gate electrode. FIG. 7 illustrates a plan structure of a semiconductor substrate 200 on which a polycrystalline silicon film 203 is patterned into the shape of a gate electrode. Furthermore, although not illustrated, an N-type extension region and a P-type pocket region are formed in the N-type MIS transistor formation region, and a P-type extension region and an N-type pocket region are formed in the P-type MIS transistor formation region. In addition, for example, an approximately 10-nm-thick TEOS film and an approximately 40-nm-thick silicon nitride film are sequentially deposited on the substrate by CVD and then etched, thereby forming sidewalls formed of the TEOS film and the silicon nitride film on both sides of the patterned polycrystalline silicon film 203 having the shape of the gate electrode.

Next, as illustrated in FIG. 5B, a resist film 204 is formed on the polycrystalline silicon film 203 to cover the P-type MIS transistor formation region and have an opening in the N-type MIS transistor formation region. Next, for example, phosphorus (P⁺) ions are introduced, as N-type impurity ions, into the polycrystalline silicon film 203 by ion implantation using the resist film 204 as a mask at an implantation energy of 20 keV and a dose of 4×10¹⁵/cm². In this way, N-type source and drain regions (not shown) are formed. Furthermore, a part of the polycrystalline silicon film 203 located in the N-type MIS transistor formation region becomes an N-type polycrystalline silicon film 203A. Thereafter, the resist film 204 is removed.

In the process step illustrated in FIG. 5B, an area of the resist film 204 in which an opening is formed (hereinafter, referred to as “opening area of the resist film 204”) includes a non-silicided area (an area in which an anti-silicidation film 207 illustrated in FIG. 6B is to be formed). In other words, the opening area of the resist film 204 extends to a closer part of the isolation region 201 to the P-type MIS transistor formation region than the middle part thereof between the N-type MIS transistor formation region and the P-type MIS transistor formation region (preferably, to the end of the isolation region 201 located adjacent to the P-type MIS transistor formation region).

Next, as illustrated in FIG. 5C, a resist film 205 is formed on the polycrystalline silicon film 203 to cover the N-type MIS transistor formation region and have an opening in the P-type MIS transistor formation region. Next, for example, boron (B+) ions are introduced, as P-type impurity ions, into the polycrystalline silicon film 203 by ion implantation using the resist film 205 as a mask at an implantation energy of 0.5 keV and a dose of 3×10¹⁵/cm². In this way, P-type source and drain regions (not shown) are formed. Furthermore, a part of the polycrystalline silicon film 203 located in the P-type MIS transistor formation region becomes a P-type polycrystalline silicon film 203B. Thereafter, the resist film 205 is removed, and then the semiconductor substrate 200 is subjected to heat treatment, thereby activating the impurity ions introduced into the polycrystalline silicon film 203. In this case, the impurity ions diffuse in the polycrystalline silicon film 203. As a result, a PN boundary is formed at the boundary between the N-type MIS transistor formation region and the P-type MIS transistor formation region (exactly, on the end of the isolation region 201 located adjacent to the P-type MIS transistor formation region).

In the process step illustrated in FIG. 5C, an area of the resist film 205 in which an opening is formed (hereinafter, referred to as “opening area of the resist film 205”) does not include a non-silicided area (an area in which an anti-silicidation film 207 illustrated in FIG. 6B is to be formed). In other words, the opening area of the resist film 205 is not formed to extend to a closer part of the isolation region 201 to the P-type MIS transistor formation region than the middle part thereof between the N-type MIS transistor formation region and the P-type MIS transistor formation region. However, a part of the opening area of the resist film 205 preferably overlaps with an end portion of the isolation region 201 located adjacent to the P-type MIS transistor formation region.

Next, as illustrated in FIG. 5D, the entire surface of the polycrystalline silicon film 203 is etched, and, for example, an approximately 80-nm-thick upper portion thereof is removed. After this etching process, the N-type polycrystalline silicon film 203A that will become a part of a gate electrode located in the N-type MIS transistor formation region and the P-type polycrystalline silicon film 203B that will become a part of the gate electrode located in the P-type MIS transistor formation region each have a thickness of, for example, approximately 70 nm.

Next, as illustrated in FIG. 6A, a resist film 206 is formed on the polycrystalline silicon film 203 to cover the N-type MIS transistor formation region and have an opening in the P-type MIS transistor formation region. Next, the P-type polycrystalline silicon film 203B is etched using the resist film 206 as a mask so that its approximately 30-nm-thick upper portion is removed. In other words, after this etching process, the P-type polycrystalline silicon film 203B that will become the part of the gate electrode located in the P-type MIS transistor formation region has a thickness of approximately 40 nm. Thereafter, the resist film 206 is removed.

In the process step illustrated in FIG. 6A, an area of the resist film 206 in which an opening is formed (hereinafter, referred to as “opening area of the resist film 206”) is preferably formed to include a non-silicided area (an area in which an anti-silicidation film 207 illustrated in FIG. 6B is to be formed). That is, it extends to a part of the polycrystalline silicon film 203 located on the middle part of the isolation region 201 between the N-type MIS transistor formation region and the P-type MIS transistor formation region. In view of the above, the thickness of a part of the N-type polycrystalline silicon film 203A located in the non-silicided region is reduced, for example, to approximately 40 nm. As a result, for example, an approximately 30-nm-high step is formed in a part of the N-type polycrystalline silicon film 203A located on the isolation region 201.

Next, as illustrated in FIG. 6B, an anti-silicidation film 207 is formed on the side of the step formed at the N-type polycrystalline silicon film 203A. In other words, the anti-silicidation film 207 at least partly covers a part of the polycrystalline silicon film 203 located on the isolation region 201. To be specific, for example, an approximately 50-nm-thick silicon oxide film is formed on the entire surface of the polycrystalline silicon film 203, and then the entire surface of the silicon oxide film is etched. In this way, an anti-silicidation film 207 serving as a film for protecting a sidewall is formed on the side of the step.

In this embodiment, an anti-silicidation film 207 is formed so as to be prevented from overlapping with the PN boundary in the polycrystalline silicon film 203. In other words, no PN boundary exists in a part of the polycrystalline silicon film 203 located under the middle part of the anti-silicidation film 207. The PN boundary may be located under an end part of the anti-silicificatin film 207 located adjacent to the P-type transistor formation region as long as it is located in a region of the polycrystalline silicon film 203 that will be formed into an Ni₃Si film 209B by silicidation in a process step illustrated in FIG. 6D. In other words, the end part of the anti-silicidation film 207 may overlap with the PN boundary.

Next, as illustrated in FIG. 6C, for example, an approximately 120-nm-thick nickel (Ni) film 208 is deposited on the polycrystalline silicon film 203 and the anti-silicidation film 206, and then the semiconductor substrate 200 is subjected to heat treatment, for example, at a temperature of approximately 320° C. for approximately 30 seconds, thereby causing a silicidation reaction between the polycrystalline silicon film 203 and the Ni film 208. Thereafter, an unreacted portion of the Ni film 208 is selectively removed, and then the semiconductor substrate 200 is additionally subjected to heat treatment, for example, at a temperature of approximately 520° C. for approximately 30 seconds. In this way, as illustrated in FIG. 6D, a NiSi film 209A is formed which will become a part of a gate electrode located in the N-type MIS transistor formation region, and a Ni₃Si film 209B is formed which will become a part of the gate electrode located in the P-type MIS transistor formation region. Furthermore, an unreacted portion of the N-type polycrystalline silicon film 203A is left, as a conductive anti-diffusion region for preventing interdiffusion between the NiSi film 209A and the Ni₃Si film 209B, on the isolation region 201, i.e., under the anti-silicidation film 207.

Since in this embodiment the polycrystalline silicon film 203 and the Ni film 208 are fully silicided, a fully silicided gate electrode formed of the NiSi film 209A is formed in the N-type MIS transistor formation region to come into contact with the first gate insulating film 202A, and a fully silicided gate electrode formed of the Ni₃Si film 209B is formed in the P-type MIS transistor formation region to come into contact with the second gate insulating film 202B.

As described above, according to the second embodiment, a part of the N-type polycrystalline silicon film 203A serving as the conductive anti-diffusion region for preventing the interdiffusion is left between the NiSi film 209A and the Ni₃Si film 209B forming parts of a fully-silicided dual-gate electrode. This can prevent such problems that due to interdiffusion between silicides, the shapes of the NiSi film 209A and the Ni₃Si film 209B are changed or the compositions of the NiSi film 209A and the Ni₃Si film 209B become instable. In view of the above, the reliability of the semiconductor device can be improved by enhancing the stability of the gate electrode.

According to the second embodiment, the conductive anti-diffusion region corresponds to the N-type polycrystalline silicon film 203A in which no PN boundary exists. This can prevent the resistance of the gate electrode from increasing due to the conductive anti-diffusion region.

Although in the second embodiment the N-type polycrystalline silicon film 203A is used as the conductive anti-diffusion region, the P-type polycrystalline silicon film 203B may be used instead. Furthermore, although the polycrystalline silicon film 203 is used as the conductive anti-diffusion region, an amorphous film may be used instead.

Although in the second embodiment silicon is used as a material of the conductive anti-diffusion region, any other conductive material, such as silicon germanium, may be used instead.

In the second embodiment, a conductive anti-diffusion region (for example, the N-type polycrystalline silicon film 203A) is formed only in a lower portion of a gate electrode located on the isolation region 201, and a NiSi film 209A and a Ni₃Si film 209B is formed to extend over the conductive anti-diffusion region. Instead of this, only any one of the NiSi film 209A and the Ni₃Si film 209B may be formed to extend over the conductive anti-diffusion region. Alternatively, the conductive anti-diffusion region formed of part of the N-type polycrystalline silicon film 203A or part of the P-type polycrystalline silicon film 203B is formed to extend from the top surface of the isolation region 201 to the back surface of the anti-silicidation film 207. Alternatively, as illustrated in FIG. 8, in a case where the interdiffusion between the NiSi film 209A and the Ni₃Si film 209B can be prevented to some extent by only the anti-silicification film 207, the N-type polycrystalline silicon film 203A or the P-type polycrystalline silicon film 203B serving as a conductive anti-diffusion region does not need to be left under the anti-silicidation film 207. Herein, the case where the interdiffusion between the NiSi film 209A and the Ni₃Si film 209B can be prevented to some extent means a case where the Ni₃Si film 209B does not reach the top surface of the first gate insulating film 202A in the N-type MIS transistor formation region or a case where the NiSi film 209A does not reach the top surface of the second gate insulating film 202B in the P-type MIS transistor formation region.

Although in the second embodiment a Ni film is used to form a fully-silicided gate electrode, any other metal film, such as a Co film, a Ti film, or a Pt film, may be used instead. In other words, the fully-silicided gate electrode may contain at least one of Co, Ti, Ni, and Pt.

Although in the second embodiment a silicon oxide film is used as the anti-silicidation film 207, a SiN film, a Ti film, a TiN film, a Ta film, a TaN film, a W film, or the like may be used instead.

In the second embodiment, the P-type polycrystalline silicon film 203B that will become a part of a gate electrode located in the P-type MIS transistor formation region has a smaller thickness than a part of the N-type polycrystalline silicon film 203A that will become a part of the gate electrode located in the N-type MIS transistor formation region. However, instead of this or in addition to this, a part of the Ni film 208 located in the P-type MIS transistor formation region may have a larger thickness than a part thereof located in the N-type MIS transistor formation region.

### Embodiment 3

A semiconductor device according to a third embodiment of the present invention and a fabrication method for the same will be described hereinafter with reference to the drawings.

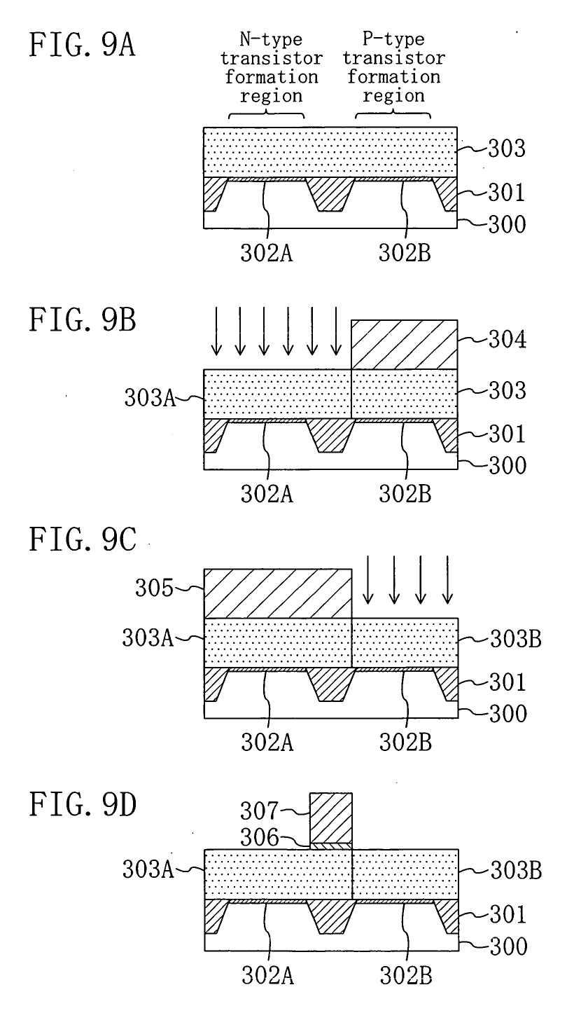

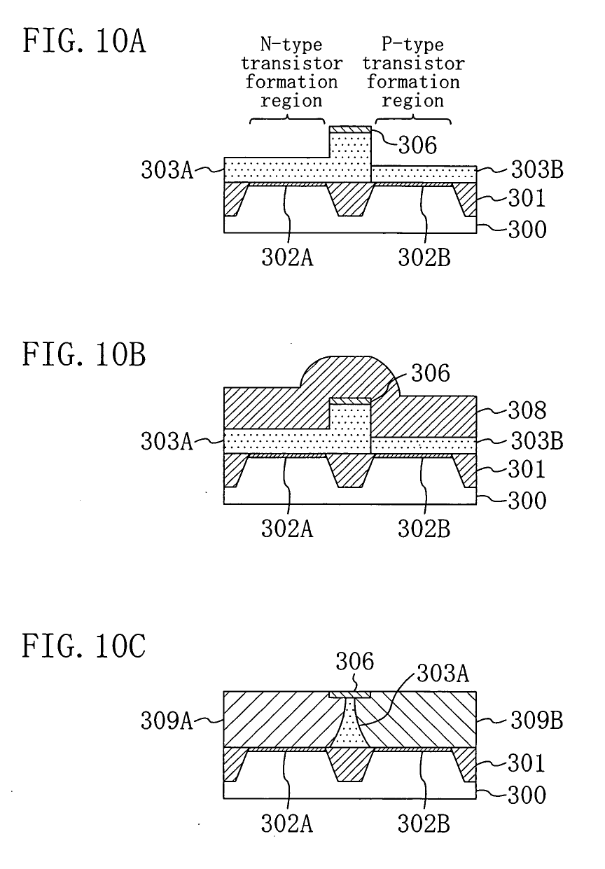

FIG. 9A through 9D and 10A through 10C are cross-sectional views taken along the gate width direction and illustrating process steps in the fabrication method for the semiconductor device according to the third embodiment, more specifically, a semiconductor device having a dual-gate structure.

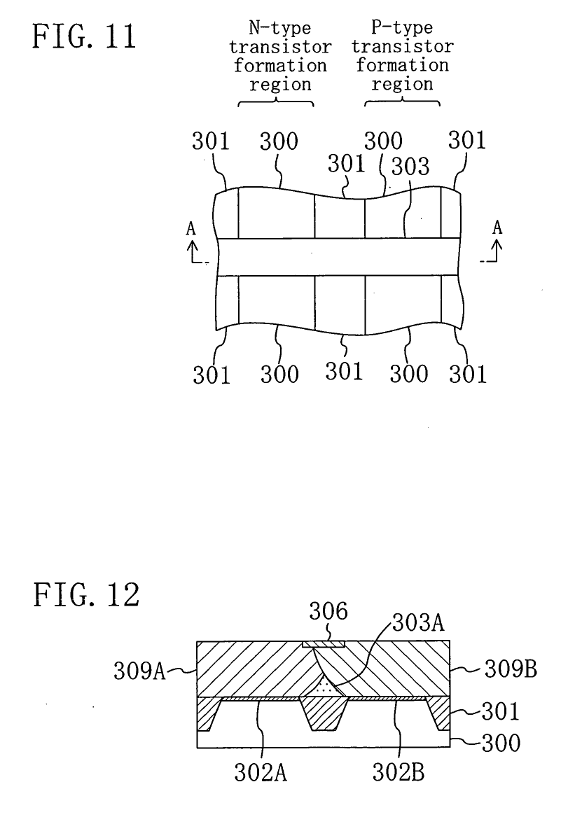

First, as illustrated in FIG. 9A, an isolation region 301 is formed in a semiconductor substrate 300 of, for example, silicon by STI to isolate an N-type MIS transistor formation region from a P-type MIS transistor formation region. Thereafter, a 2-nm-thick first gate insulating film 302A and a 2-nm-thick second gate insulating film 302B both formed of, for example, a silicon oxide film are formed on parts of the semiconductor substrate 300 located in the N-type MIS transistor formation region and the P-type MIS transistor formation region, respectively. Then, for example, a 150-nm-thick polycrystalline silicon film 303 is formed on the entire surface of the semiconductor substrate 300. In order to prevent various ions from being implanted into a channel region in implantation of the ions that will be described below, the polycrystalline silicon film 303 is set to have a larger thickness. Subsequently, the polycrystalline silicon film 303 and a set of the gate insulating films 302A and 302B are sequentially etched by photolithography and RIE, thereby patterning the polycrystalline silicon film 303 into the shape of a gate electrode. FIG. 11 illustrates a plan structure of a semiconductor substrate 300 on which a polycrystalline silicon film 303 is patterned into the shape of the gate electrode. Furthermore, although not illustrated, an N-type extension region and a P-type pocket region are formed in the N-type MIS transistor formation region, and a P-type extension region and an N-type pocket region are formed in the P-type MIS transistor formation region. In addition, for example, an approximately 10-nm-thick TEOS film and an approximately 40-nm-thick silicon nitride film are sequentially deposited on the substrate by CVD and then etched, thereby forming sidewalls formed of the TEOS film and the silicon nitride film on both sides of the patterned polycrystalline silicon film 303 having the shape of the gate electrode.

Next, as illustrated in FIG. 9B, a resist film 304 is formed on the polycrystalline silicon film 303 to cover the P-type MIS transistor formation region and have an opening in the N-type MIS transistor formation region. Next, for example, phosphorus (P⁺) ions are introduced, as N-type impurity ions, into the polycrystalline silicon film 303 by ion implantation using the resist film 304 as a mask at an implantation energy of 20 keV and a dose of 4×10¹⁵/cm². In this way, N-type source and drain regions (not shown) are formed. Furthermore, a part of the polycrystalline silicon film 303 located in the N-type MIS transistor formation region becomes an N-type polycrystalline silicon film 303A. Thereafter, the resist film 304 is removed.

In the process step illustrated in FIG. 9B, an area of the resist film 304 in which an opening is formed (hereinafter, referred to as “opening area of the resist film 304”) includes a non-silicided area (an area in which an anti-silicidation film 306 illustrated in FIG. 9D is to be formed). In other words, the opening area of the resist film 304 extends to a closer part of the isolation region 301 to the P-type MIS transistor formation region than the middle part thereof between the N-type MIS transistor formation region and the P-type MIS transistor formation region (preferably, to the end of the isolation region 301 located adjacent to the P-type MIS transistor formation region).

Next, as illustrated in FIG. 9C, a resist film 305 is formed on the polycrystalline silicon film 303 to cover the N-type MIS transistor formation region and have an opening in the P-type MIS transistor formation region. Next, for example, boron (B+) ions are introduced, as P-type impurity ions, into the polycrystalline silicon film 303 by ion implantation using the resist film 305 as a mask at an implantation energy of 0.5 keV and a dose of 3×10¹⁵/cm². In this way, P-type source and drain regions (not shown) are formed. Furthermore, a part of the polycrystalline silicon film 303 located in the P-type MIS transistor formation region becomes a P-type polycrystalline silicon film 303B. Thereafter, the resist film 305 is removed, and then the semiconductor substrate 300 is subjected to heat treatment, thereby activating the impurity ions introduced into the polycrystalline silicon film 303. In this case, the impurity ions diffuse in the polycrystalline silicon film 303. As a result, a PN boundary is formed at the boundary between the N-type MIS transistor formation region and the P-type MIS transistor formation region (exactly, on the end of the isolation region 301 located adjacent to the P-type MIS transistor formation region).

In the process step illustrated in FIG. 9C, an area of the resist film 305 in which an opening is formed (hereinafter, referred to as “opening area of the resist film 305”) does not include a non-silicided area (an area in which an anti-silicidation film 306 illustrated in FIG. 9D is to be formed). In other words, the opening area of the resist film 305 is not formed to extend to a closer part of the isolation region 301 to the P-type MIS transistor formation region than the middle part thereof between the N-type MIS transistor formation region and the P-type MIS transistor formation region. However, a part of the opening area of the resist film 305 preferably overlaps with an end portion of the isolation region 301 located adjacent to the P-type MIS transistor formation region.

Next, as illustrated in FIG. 9D, an anti-silicidation film 306 is formed to cover at least one part of the polycrystalline silicon film 303 located on the isolation region 301 between the N-type MIS transistor formation region and the P-type MIS transistor formation region. To be specific, for example, an approximately 50-nm-thick silicon oxide film is formed on the entire surface of the polycrystalline silicon film 303, and then a resist film 307 is formed by lithography to cover an area in which an anti-silicidation film is to be formed. Thereafter, the silicon oxide film is etched using the resist film 307 as a mask, thereby forming an anti-silicidation film 306. Thereafter, the resist film 307 is removed.

In this embodiment, one end of the anti-silicidation film 306 is aligned with the PN boundary in the polycrystalline silicon film 303. In other words, the anti-silicidation film 306 is formed on an end part of the N-type polycrystalline silicon film 303A located on the isolation region 301, and thus the PN boundary does not exist under the middle part of the anti-silicidation film 306. The PN boundary may be located under an end part of the anti-silicificatin film 306 located adjacent to the P-type transistor formation region as long as it is located in a region of the polycrystalline silicon film 303 that will be formed into an Ni₃Si film 309B by silicidation in a process step illustrated in FIG. 10C. In other words, the end part of the anti-silicidation film 306 may overlap with the PN boundary.

Next, a resist film (not shown) is formed on the polycrystalline silicon film 303 to cover the P-type MIS transistor formation region and have an opening in the N-type MIS transistor formation region. In this case, an area of the resist film in which an opening is formed may overlap with part of the anti-silicidation film 306. Next, the N-type polycrystalline silicon film 303A is etched using the resist film as a mask so that, for example, its approximately 80-nm-thick upper portion is removed as illustrated in FIG. 10A. In other words, after this etching process, the N-type polycrystalline silicon film 303A that will become a part of a gate electrode located in the N-type MIS transistor formation region has a thickness of approximately 70 nm. Thereafter, the resist film is removed.

Next, a resist film (not shown) is formed on the polycrystalline silicon film 303 to cover the N-type MIS transistor formation region and have an opening in the P-type MIS transistor formation region. In this case, an area of the resist film in which an opening is formed may overlap with part of the anti-silicidation film 306. Next, the P-type polycrystalline silicon film 303B is etched using the resist film as a mask so that, for example, its approximately 110-nm-thick upper portion is removed as illustrated in FIG. 10A. In other words, after this etching process, the P-type polycrystalline silicon film 303B that will become a part of a gate electrode located in the P-type MIS transistor formation region has a thickness of approximately 40 nm. Thereafter, the resist film is removed.

Next, as illustrated in FIG. 10B, for example, an approximately 120-nm-thick nickel (Ni) film 308 is deposited on the polycrystalline silicon film 303 and the anti-silicidation film 306, and then the semiconductor substrate 300 is subjected to heat treatment, for example, at a temperature of approximately 320° C. for approximately 30 seconds, thereby causing a silicidation reaction between the polycrystalline silicon film 303 and the Ni film 308. Thereafter, an unreacted portion of the Ni film 308 is selectively removed, and then the semiconductor substrate 300 is additionally subjected to heat treatment, for example, at a temperature of approximately 520° C. for approximately 30 seconds. In this way, as illustrated in FIG. 10C, a NiSi film 309A is formed which will become a part of a gate electrode located in the N-type MIS transistor formation region, and a Ni₃Si film 309B is formed which will become a part of the gate electrode located in the P-type MIS transistor formation region. Furthermore, an unreacted portion of the N-type polycrystalline silicon film 303A is left, as a conductive anti-diffusion region for preventing interdiffusion between the NiSi film 309A and the Ni₃Si film 309B, on the isolation region 301, i.e., under the anti-silicidation film 307.

Since in this embodiment the polycrystalline silicon film 303 and the Ni film 308 are fully silicided, a fully silicided gate electrode formed of the NiSi film 309A is formed in the N-type MIS transistor formation region to come into contact with the first gate insulating film 302A, and a fully silicided gate electrode formed of the Ni₃Si film 309B is formed in the P-type MIS transistor formation region to come into contact with the second gate insulating film 302B.

As described above, according to the third embodiment, a part of the N-type polycrystalline silicon film 303A serving as the conductive anti-diffusion region for preventing the interdiffusion is left between the NiSi film 309A and the Ni₃Si film 309B forming parts of a fully-silicided dual-gate electrode. This can prevent such problems that due to interdiffusion between silicides, the shapes of the NiSi film 309A and the Ni₃Si film 309B are changed or the compositions of the NiSi film 309A and the Ni₃Si film 309B become instable. In view of the above, the reliability of the semiconductor device can be improved by enhancing the stability of the gate electrode.

According to the third embodiment, the conductive anti-diffusion region corresponds to the N-type polycrystalline silicon film 303A in which no PN boundary exists. This can prevent the resistance of the gate electrode from increasing due to the conductive anti-diffusion region.

Although in the third embodiment the N-type polycrystalline silicon film 303A is used as the conductive anti-diffusion region, the P-type polycrystalline silicon film 303B may be used instead. Furthermore, although the polycrystalline silicon film 303 is used as the conductive anti-diffusion region, an amorphous film may be used instead.

Although in the third embodiment silicon is used as a material of the conductive anti-diffusion region, any other conductive material, such as silicon germanium, may be used instead.

In the third embodiment, the conductive anti-diffusion region formed of the N-type polycrystalline silicon film 303A is formed to extend from the top surface of the isolation region 301 to the back surface of the anti-silicidation film 306. However, otherwise, for example, as illustrated in FIG. 12, a conductive anti-diffusion region (for example, the N-type polycrystalline silicon film 303A) may be formed only in a lower portion of a gate electrode located on the isolation region 301, and both or one of a NiSi film 309A and a Ni₃Si film 309B may be formed to extend over the conductive anti-diffusion region.

Although in the third embodiment a Ni film is used to form fully-silicided gate electrodes, any other metal film, such as a Co film, a Ti film, or a Pt film, may be used instead. In other words, the fully-silicided gate electrode may contain at least one of Co, Ti, Ni, and Pt.

Although in the third embodiment a silicon oxide film is used as the anti-silicidation film 306, a SiN film, a Ti film, a TiN film, a Ta film, a TaN film, a W film, or the like may be used instead.

In the third embodiment, the P-type polycrystalline silicon film 303B that will become a part of a gate electrode located in the P-type MIS transistor formation region has a smaller thickness than the N-type polycrystalline silicon film 303A that will become a part of a gate electrode located in the N-type MIS transistor formation region. However, instead of this or in addition to this, a part of the Ni film 308 located in the P-type MIS transistor formation region may have a larger thickness than a part thereof located in the N-type MIS transistor formation region.

### Embodiment 4

A semiconductor device according to a fourth embodiment of the present invention and a fabrication method for the same will be described hereinafter with reference to the drawings.

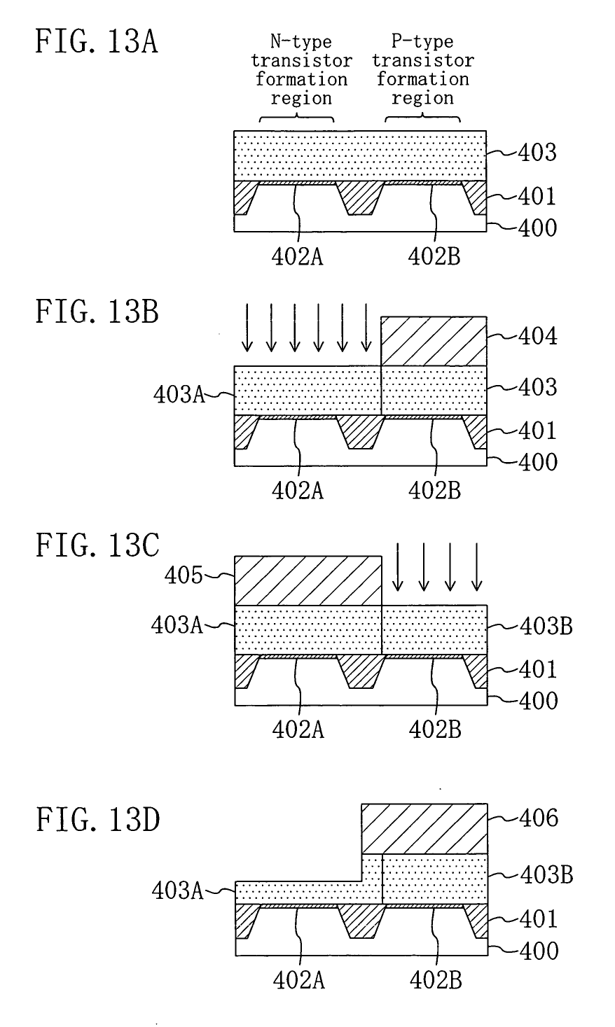

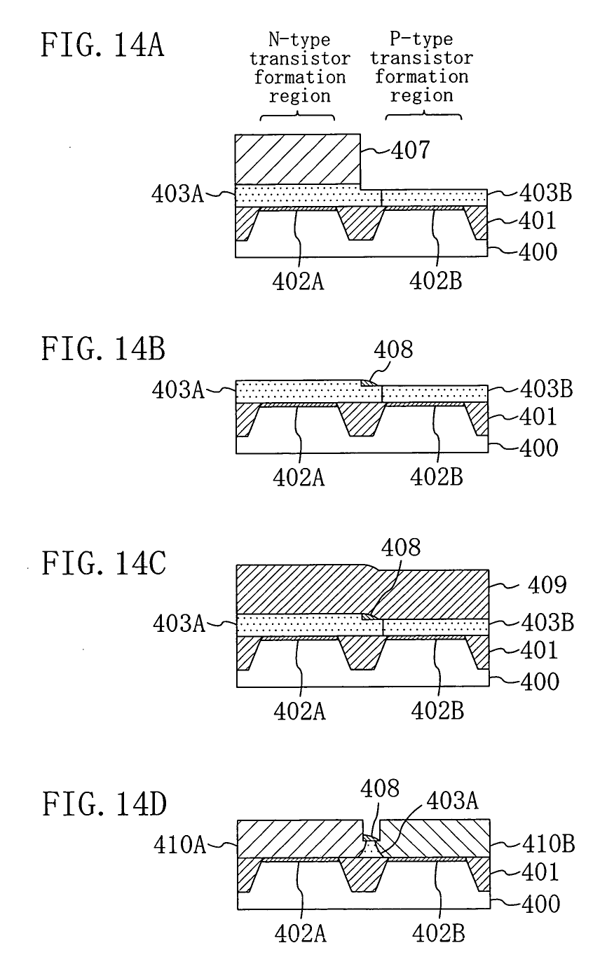

FIG. 13A through 13D and 14A through 14D are cross-sectional views taken along the gate width direction and illustrating process steps in the fabrication method for the semiconductor device according to the fourth embodiment, more specifically, a semiconductor device having a dual-gate structure.

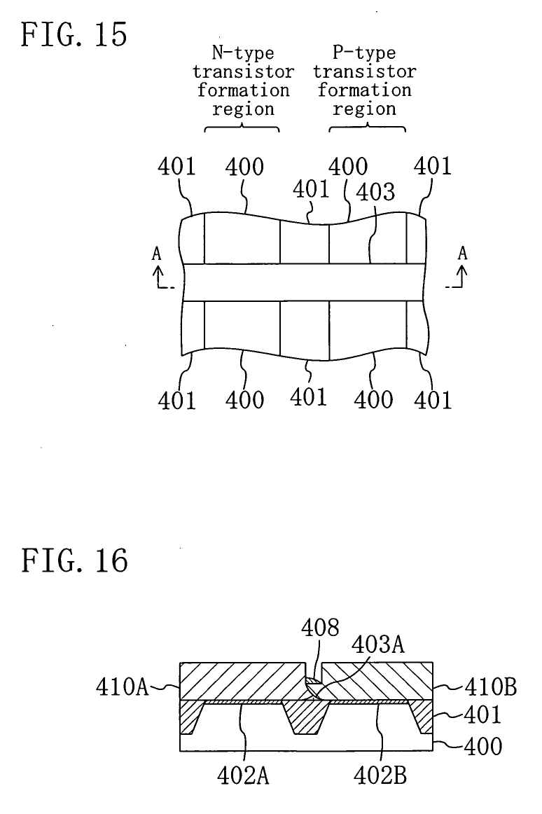

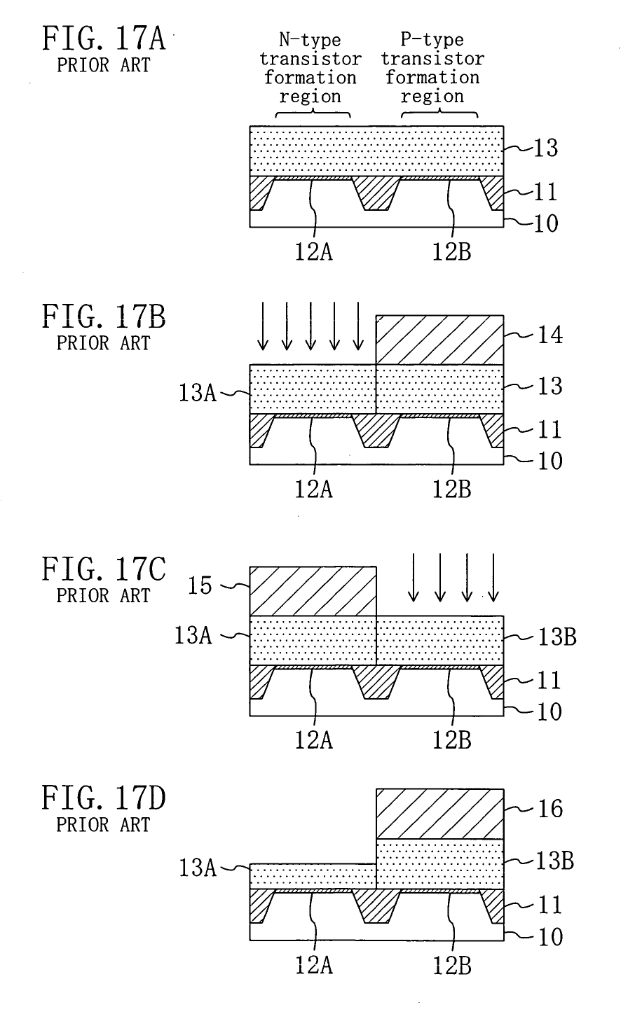

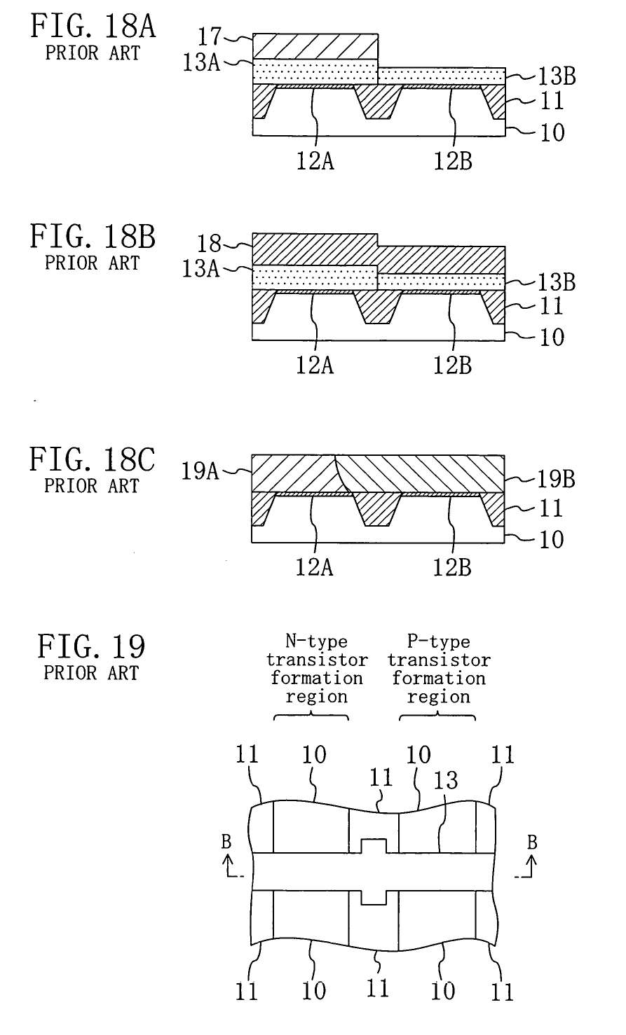

First, as illustrated in FIG. 13A, an isolation region 401 is formed in a semiconductor substrate 400 of, for example, silicon by STI to isolate an N-type MIS transistor formation region from a P-type MIS transistor formation region. Thereafter, a 2-nm-thick first gate insulating film 402A and a 2-nm-thick second gate insulating film 402B both formed of, for example, a silicon oxide film are formed on parts of the semiconductor substrate 400 located in the N-type MIS transistor formation region and the P-type MIS transistor formation region, respectively. Then, for example, a 150-nm-thick polycrystalline silicon film 403 is formed on the entire surface of the semiconductor substrate 400. In order to prevent various ions from being implanted into a channel region in implantation of the ions that will be described below, the polycrystalline silicon film 403 is set to have a larger thickness. Subsequently, the polycrystalline silicon film 403 and a set of the gate insulating films 402A and 402B are sequentially etched by photolithography and RIE, thereby patterning the polycrystalline silicon film 403 into the shape of a gate electrode. FIG. 15 illustrates a plan structure of a semiconductor substrate 400 on which a polycrystalline silicon film 403 is patterned into the shape of a gate electrode. Furthermore, although not illustrated, an N-type extension region and a P-type pocket region are formed in the N-type MIS transistor formation region, and a P-type extension region and an N-type pocket region are formed in the P-type MIS transistor formation region. In addition, for example, an approximately 10-nm-thick TEOS film and an approximately 40-nm-thick silicon nitride film are sequentially deposited on the substrate by CVD and then etched, thereby forming sidewalls formed of the TEOS film and the silicon nitride film on both sides of the patterned polycrystalline silicon film 403 having the shape of the gate electrode.

Next, as illustrated in FIG. 13B, a resist film 404 is formed on the polycrystalline silicon film 403 to cover the P-type MIS transistor formation region and have an opening in the N-type MIS transistor formation region. Next, for example, phosphorus (P⁺) ions are introduced, as N-type impurity ions, into the polycrystalline silicon film 403 by ion implantation using the resist film 404 as a mask at an implantation energy of 20 keV and a dose of 4×10¹⁵/cm². In this way, N-type source and drain regions (not shown) are formed. Furthermore, a part of the polycrystalline silicon film 403 located in the N-type MIS transistor formation region becomes an N-type polycrystalline silicon film 403A. Thereafter, the resist film 404 is removed.

In the process step illustrated in FIG. 13B, an area of the resist film 404 in which an opening is formed (hereinafter, referred to as “opening area of the resist film 404”) includes a non-silicided area (an area in which an anti-silicidation film 408 illustrated in FIG. 14B is to be formed). In other words, the opening area of the resist film 404 extends to a closer part of the isolation region 401 to the P-type MIS transistor formation region than the middle part thereof between the N-type MIS transistor formation region and the P-type MIS transistor formation region (preferably, to the end of the isolation region 401 located adjacent to the P-type MIS transistor formation region).

Next, as illustrated in FIG. 13C, a resist film 405 is formed on the polycrystalline silicon film 403 to cover the N-type MIS transistor formation region and have an opening in the P-type MIS transistor formation region. Next, for example, boron (B+) ions are introduced, as P-type impurity ions, into the polycrystalline silicon film 403 by ion implantation using the resist film 405 as a mask at an implantation energy of 0.5 keV and a dose of 3×10¹⁵/cm². In this way, P-type source and drain regions (not shown) are formed. Furthermore, a part of the polycrystalline silicon film 403 located in the P-type MIS transistor formation region becomes a P-type polycrystalline silicon film 403B. Thereafter, the resist film 405 is removed, and then the semiconductor substrate 400 is subjected to heat treatment, thereby activating the impurity ions introduced into the polycrystalline silicon film 403. In this case, the impurity ions diffuse in the polycrystalline silicon film 403. As a result, a PN boundary is formed at the boundary between the N-type MIS transistor formation region and the P-type MIS transistor formation region (exactly, on the end of the isolation region 401 located adjacent to the P-type MIS transistor formation region).

In the process step illustrated in FIG. 13C, an area of the resist film 405 in which an opening is formed (hereinafter, referred to as “opening area of the resist film 405”) does not include a non-silicided area (an area in which an anti-silicidation film 408 illustrated in FIG. 14B is to be formed). In other words, the opening area of the resist film 405 is not formed to extend to a closer part of the isolation region 401 to the P-type MIS transistor formation region than the middle part thereof between the N-type MIS transistor formation region and the P-type MIS transistor formation region. However, a part of the opening area of the resist film 405 preferably overlaps with an end portion of the isolation region 401 located adjacent to the P-type MIS transistor formation region.

Next, as illustrated in FIG. 13D, a resist film 406 is formed on the polycrystalline silicon film 403 to cover the P-type MIS transistor formation region and have an opening in the N-type MIS transistor formation region. Next, the N-type polycrystalline silicon film 403A is etched using the resist film 406 as a mask so that, for example, its approximately 80-nm-thick upper portion is removed. In other words, after this etching process, the N-type polycrystalline silicon film 403A that will become a part of a gate electrode located in the N-type MIS transistor formation region has a thickness of approximately 70 nm. Thereafter, the resist film 406 is removed.

In the process step illustrated in FIG. 13D, an area of the resist film 406 in which an opening is formed (hereinafter, referred to as “opening area of the resist film 406”) does not include a non-silicided area (an area in which an anti-silicidation film 408 illustrated in FIG. 14B is to be formed). In view of the above, a part of the N-type polycrystalline silicon film 403A located in the non-silicided area has the same thickness as just after the deposition of the polycrystalline silicon film 403, i.e., a thickness of approximately 150 nm.

Next, as illustrated in FIG. 14A, a resist film 407 is formed on the polycrystalline silicon film 403 to cover the N-type MIS transistor formation region and have an opening in the P-type MIS transistor formation region. Next, the P-type polycrystalline silicon film 403B is etched using the resist film 407 as a mask so that, for example, its approximately 10-nm-thick upper portion is removed. In other words, after this etching process, the P-type polycrystalline silicon film 403B that will become a part of the gate electrode located in the P-type MIS transistor formation region has a thickness of approximately 40 nm. Thereafter, the resist film 407 is removed.

In the process step illustrated in FIG. 14A, an area of the resist film 407 in which an opening is formed (hereinafter, referred to as “opening area of the resist film 407”) is preferably formed to include a non-silicided area (an area in which an anti-silicidation film 408 illustrated in FIG. 14B is to be formed). That is, it extends toward a part of the polycrystalline silicon film 403 located on the middle part of the isolation region 401 between the N-type MIS transistor formation region and the P-type MIS transistor formation region. In view of the above, the thickness of a part of the N-type polycrystalline silicon film 403A located in the non-silicided region is reduced, for example, to approximately 40 nm. As a result, for example, an approximately 30-nm-high step is formed in a part of the N-type polycrystalline silicon film 403A located on the isolation region 401.

Next, as illustrated in FIG. 14B, an anti-silicidation film 408 is formed on the side of the step formed at the N-type polycrystalline silicon film 403A. In other words, the anti-silicidation film 408 at least partly covers a part of the polycrystalline silicon film 403 located on the isolation region 401. To be specific, for example, an approximately 50-nm-thick silicon oxide film is formed on the entire surface of the polycrystalline silicon film 403, and then the entire surface of the silicon oxide film is etched. In this way, an anti-silicidation film 408 serving as a film for protecting a sidewall is formed on the side of the step.

In this embodiment, an anti-silicidation film 408 is formed so as to be prevented from overlapping with the PN boundary in the polycrystalline silicon film 403. In other words, no PN boundary exists in a part of the polycrystalline silicon film 403 located under the anti-silicidation film 408. The PN boundary may be located under an end part of the anti-silicificatin film 408 located adjacent to the P-type transistor formation region as long as it is located in a region of the polycrystalline silicon film 403 that will be formed into an Ni₃Si film 410B by silicidation in a process step illustrated in FIG. 14D. In other words, the end part of the anti-silicidation film 408 may overlap with the PN boundary.

Next, as illustrated in FIG. 14C, for example, an approximately 120-nm-thick nickel (Ni) film 409 is deposited on the polycrystalline silicon film 403 and the anti-silicidation film 408, and then the semiconductor substrate 400 is subjected to heat treatment, for example, at a temperature of approximately 320° C. for approximately 30 seconds, thereby causing a silicidation reaction between the polycrystalline silicon film 403 and the Ni film 409. Thereafter, an unreacted portion of the Ni film 409 is selectively removed, and then the semiconductor substrate 400 is additionally subjected to heat treatment, for example, at a temperature of approximately 520° C. for approximately 30 seconds. In this way, as illustrated in FIG. 14D, an NiSi film 410A is formed which will become a part of a gate electrode located in the N-type MIS transistor formation region, and an Ni₃Si film 410B is formed which will become a part of the gate electrode located in the P-type MIS transistor formation region. Furthermore, an unreacted portion of the N-type polycrystalline silicon film 403A is left, as a conductive anti-diffusion region for preventing interdiffusion between the NiSi film 410A and the Ni₃Si film 410B, on the isolation region 401, i.e., under the anti-silicidation film 408.

Since in this embodiment the polycrystalline silicon film 403 and the Ni film 409 are fully silicided, a fully silicided gate electrode formed of the NiSi film 410A is formed in the N-type MIS transistor formation region to come into contact with the first gate insulating film 402A, and a fully silicided gate electrode formed of the Ni₃Si film 410B is formed in the P-type MIS transistor formation region to come into contact with the second gate insulating film 402B.

As described above, according to the fourth embodiment, a part of the N-type polycrystalline silicon film 403A serving as the conductive anti-diffusion region for preventing the interdiffusion is left between the NiSi film 410A and the Ni₃Si film 410B forming parts of the fully-silicided dual-gate electrode. This can prevent such problems that due to interdiffusion between suicides, the shapes of the NiSi film 410A and the Ni₃Si film 410B are changed or the compositions of the NiSi film 410A and the Ni₃Si film 410B become instable. In view of the above, the reliability of the semiconductor device can be improved by enhancing the stability of the gate electrode.

According to the fourth embodiment, the conductive anti-diffusion region corresponds to the N-type polycrystalline silicon film 403A in which no PN boundary exists. This can prevent the resistance of the gate electrode from increasing due to the conductive anti-diffusion region.

Although in the fourth embodiment the N-type polycrystalline silicon film 403A is used as the conductive anti-diffusion region, the P-type polycrystalline silicon film 403B may be used instead. Furthermore, although the polycrystalline silicon film 403 is used as the conductive anti-diffusion region, an amorphous film may be used instead.

Although in the fourth embodiment silicon is used as a material of the conductive anti-diffusion region, any other conductive material, such as silicon germanium, may be used instead.

In the fourth embodiment, the conductive anti-diffusion region formed of the N-type polycrystalline silicon film 403A is formed to extend from the top surface of the isolation region 401 to the back surface of the anti-silicidation film 408. However, otherwise, for example, as illustrated in FIG. 16, a conductive anti-diffusion region (for example, the N-type polycrystalline silicon film 403A) may be formed only in a lower portion of the gate electrode located on the isolation region 401, and both or one of an NiSi film 410A and an Ni₃Si film 410B may be formed to extend over the conductive anti-diffusion region.

Although in the fourth embodiment a Ni film is used to form a fully-silicided gate electrode, any other metal film, such as a Co film, a Ti film, or a Pt film, may be used instead. In other words, the fully-silicided gate electrode may contain at least one of Co, Ti, Ni, and Pt.

Although in the fourth embodiment a silicon oxide film is used as the anti-silicidation film 408, a SiN film, a Ti film, a TiN film, a Ta film, a TaN film, a W film, or the like may be used instead.

In the fourth embodiment, the P-type polycrystalline silicon film 403B that will become a part of a gate electrode located in the P-type MIS transistor formation region has a smaller thickness than the N-type polycrystalline silicon film 403A that will become a part of the gate electrode located in the N-type MIS transistor formation region. However, instead of this or in addition to this, a part of the Ni film 409 located in the P-type MIS transistor formation region may have a larger thickness than a part thereof located in the N-type MIS transistor formation region.

What is claimed is:

1. A semiconductor device comprising:
a first element region and a second element region formed on a substrate to be adjacent to each other with an isolation region interposed therebetween;
a first gate insulating film formed on the first element region;
a second gate insulating film formed on the second element region; and
a gate electrode continuously formed on the first gate insulating film, the isolation region and the second gate insulating film,
wherein the gate electrode includes a first silicided region formed to come into contact with the first gate insulating film, a second silicided region which is formed to come into contact with the second gate insulating film and is of a different composition from the first silicided region, and a conductive anti-diffusion region composed of a non-silicided region formed in a part of the gate electrode located on the isolation region and between the first element region and the second element region.

2. The semiconductor device of claim 1, wherein
the conductive anti-diffusion region is a silicon region.

3. The semiconductor device of claim 2 further comprising:
an impurity region of a first conductivity type formed in the first element region and an impurity region of a second conductivity type formed in the second element region,
wherein the silicon region is of the first conductivity type.

4. The semiconductor device of claim 2 further comprising:
an impurity region of a first conductivity type formed in the first element region and an impurity region of a second conductivity type formed in the second element region,
wherein the silicon region is of the second conductivity type.

5. The semiconductor device of claim 2, wherein
the silicon region contains germanium.

6. The semiconductor device of claim 1, wherein
the conductive anti-diffusion region is formed in a lower portion of the gate electrode located on the isolation region; and
at least one of the first silicided region and the second silicided region extends over the conductive anti-diffusion region.

7. The semiconductor device of claim 1, wherein
the first and second silicided regions contain at least one of Co, Ti, Ni, and Pt.

8. The semiconductor device of claim 1, wherein
an anti-silicidation film is formed on the conductive anti-diffusion region.

9. A method for fabricating a semiconductor device, said method comprising the steps of:
(a) forming, on a substrate, a first element region and a second element region to be adjacent to each other with an isolation region interposed therebetween;
(b) forming a first gate insulating film and a second gate insulating film on the first element region and the second element region, respectively;
(c) continuously forming a silicon film that will become a gate electrode on the first gate insulating film, the isolation region and the second gate insulating film;
(d) introducing an impurity of a first conductivity type into a part of the silicon film located on the first element region;
(e) introducing an impurity of a second conductivity type into a part of the silicon film located on the second element region;
(f) after the steps (d) and (e), forming an anti-silicidation film to at least partly cover a part of the silicon film located on the isolation region; and
(g) after the step (f), forming a first silicided region by fully siliciding a part of the silicon film located on the first gate insulating film and forming a second silicided region by fully siliciding a part of the silicon film located on the second gate insulating film,
wherein in the step (g), the first and second silicided regions are formed to be of different compositions and a conductive anti-diffusion region formed of part of the silicon film is left under the anti-silicidation film.

10. The method of claim 9, wherein
the step (g) includes the step of forming a metal film on the silicon film and the anti-silicidation film, then causing the silicon film and the metal film to react with each other by heat treatment, and thereafter removing an unreacted portion of the metal film, thereby forming the first silicided region and the second silicided region.

11. The method of claim 10, wherein
the metal film used in the step (g) contains at least one of Co, Ti, Ni, and Pt.

12. The method of claim 10, wherein
the impurity of the first conductivity type is an N-type impurity,
the impurity of the second conductivity type is a P-type impurity, and
in the step (g), a part of the metal film located on the second element region has a larger thickness than a part thereof located on the first element region.

13. The method of claim 9, wherein
a part of the silicon film that will become the conductive anti-diffusion region is of the first conductivity type.

14. The method of claim 9, wherein
a part of the silicon film that will become the conductive anti-diffusion region is of the second conductivity type.

15. The method of claim 9, wherein
the anti-silicidation film is formed of a silicon oxide film or a silicon nitride film.

16. The method of claim 9, wherein
the silicon film contains germanium.

17. The method of claim 9, wherein
in the step (g), at least one of the first silicided region and the second silicided region is formed to extend over the conductive anti-diffusion region.

18. The method of claim 9 further comprising the step of
after the step (c), reducing the thicknesses of parts of the silicon film located on at least the first and second element regions.

19. The method of claim 9, wherein
the impurity of the first conductivity type is an N-type impurity,
the impurity of the second conductivity type is a P-type impurity, and
the method further comprises the step of
after the step (c), making a part of the silicon film located on the second element region thinner than a part thereof located on the first element region.
